(19) United States
(12) Patent Application Publication
(10) Pub. No.: US 2007/0290673 A1
(43) Pub. Date: Dec. 20, 2007

(54) Portable Electric Testing Equipment

(76) Inventors: Jun Seok Kim, Gwangju Metropolitan City (KR); Joo Yong Kang, Gwangiu Metropolitan City (KR)

Correspondence Address: KNOBBE MARTENS OLSON & BEAR LLP, 2040 MAIN STREET, FOURTEENTH FLOOR, IRVINE, CA, 92614, US

(21) Appl. No.: 10/581,021

(22) PCT Filed: Nov. 26, 2004
(86) PCT No.: PCT/KR05/03087

§ 371 Date: Feb. 21, 2007

(30) Foreign Application Priority Data
Sep. 16, 2004 (KR) 20-2004-0026575

(51) Int. Cl. G01R 1/38

(52) U.S. Cl. 324/115

(57) ABSTRACT

A portable electric testing equipment comprising: a probe; ground contact means for contacting a ground terminal of a measured object; a voltage input unit for receiving a voltage applied from the probe; a controller for applying a test voltage of a prescribed level to the voltage input unit, and outputting a control signal for indicating a ground when a voltage level inputted from the voltage input unit is below zero level and for indicating a measurement stand-by state when the voltage level is at test voltage level and for indicating a detected voltage level when the voltage level is above a prescribed reference voltage; and display means for performing an indication according to the control signal from the controller, such that the measurement stand-by state can be easily recognized by a user, and a plurality of lamps are selectively illuminated for the user to intuitively recognize a measured voltage.

### FIELD OF THE INVENTION

The present invention generally relates to a portable electric testing equipment and, more particularly, to a portable electric testing equipment capable of detecting and indicating a measurement stand-by state.

### BACKGROUND OF THE INVENTION

In general, relative concepts, rather than absolute numerical values, have been introduced in checking electrical conditions of a vehicle, and this trend is more apparent when electrical elements work with mechanical elements. Automobile service technicians are nowadays required to have a basic knowledge of both electrical and mechanical fields rather than solely concentrating in the mechanical field.

However, it is essential for automobile service technicians to have knowledge of technical fields both in mechanical and electrical/electronic areas, as demands have increased in the number of electrical and electronic equipments for being used in an automobile since the adoption of complex mechatronics to the automobiles.

Lamp testers and digital multi-meters are used by service technicians for testing voltages and frequencies of electric and electronic equipments in an automobile. A lamp tester is designed to allow a technician to intuitively recognize voltages, frequencies and the like when a lamp is lighted by a given voltage and frequency according to a contact of a probe to an object to be tested. A digital multi-meter digitally measures resistances, currents, voltages (AC/DC) and the like, and displays them on a Liquid Crystal Diode or a segment display element when a probe contacts a terminal of a measured object.

However, there is a drawback in the lamp testers and the digital multi-meters according to the prior arts in that a zero potential is indicated on a display panel both when a probe contacts a ground terminal of a measured object and when no probe contacts a terminal of an object, i.e., in an open circuit state, making it impossible to discriminate whether a present state is an open circuit state (where no probe contacts a terminal) or a measurement stand-by state.

The present invention is disclosed to solve the afore-mentioned conventional technical drawback and it is an object of the present invention to provide portable electric testing equipment capable of detecting and indicating a measurement stand-by state.

### SUMMARY OF THE INVENTION

In accordance with a preferred embodiment of the present invention, the portable electric testing equipment comprises: a probe; ground contact means for contacting a ground terminal of a measured object; a voltage input unit for receiving a voltage applied from the probe; a controller for applying a test voltage of a prescribed level to the voltage input unit, and outputting a control signal for indicating a ground when a voltage level inputted from the voltage input unit is below zero level and for indicating a measurement stand-by state when the voltage level is a test voltage level and for indicating a detected voltage level when the voltage level is above a prescribed reference voltage; and display means for performing an indication according to the control signal from the controller.

### BRIEF DESCRIPTION OF THE DRAWINGS

For a better understanding of the nature and objects of the present invention, reference should be made to the following detailed description with the accompanying drawings, in which:

FIG. 1 is an external view of a portable electric testing equipment according to a preferred embodiment of the present invention;

FIG. 2 is a plan of a display/manipulation panel;

FIG. 3 is a circuit diagram of a body illustrated in FIG. 1;

FIG. 4 is a circuit diagram of a voltage input unit illustrated in FIG. 3;

FIG. 5 is a time chart for explaining an operation of the present invention according to an input voltage; and

FIG. 6 is a schematic drawing of the present invention shown in actual use.

### DESCRIPTION OF THE PREFERRED EMBODIMENT

The preferred embodiment of the present invention will now be described in detail with reference to the annexed drawings, where the present embodiment is not limiting the scope of the present invention but is given only as an illustrative purpose.

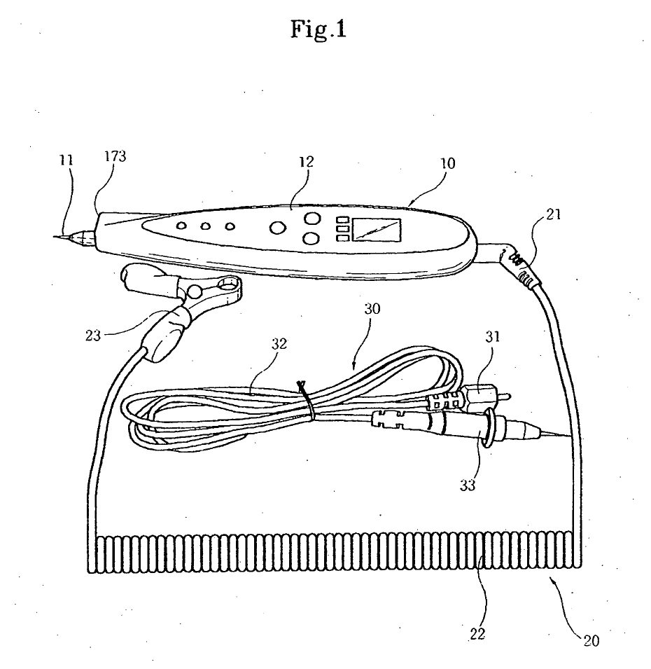

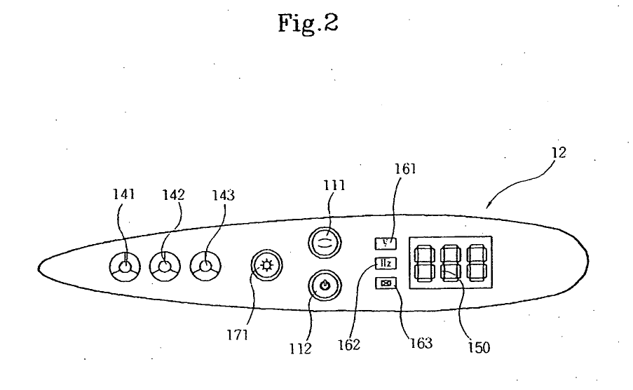

Referring to FIG. 1, the portable electric testing equipment according to the preferred embodiment of the present invention has a handheld pen-like shape. The equipment is disposed at one end thereof with a probe (11) and at the other end with a jack (not shown) for contacting a ground end. The equipment is further mounted at one surface thereof with a body (10) disposed with a display/manipulation panel (12 see FIG. 2) and a ground contact means (20) equipped with a plug (21) attachably and detachably coupled to said jack of the body (10), a cable (22) and a terminal-contacting tong (23).

The equipment may further include probe extension means (30) having an attachable/detachable coupling unit (31), an extension cable (32), and an auxiliary probe (33) connected to the extension cable (32). The probe extension means (30) is not an essential element of the present invention, but an optional element.

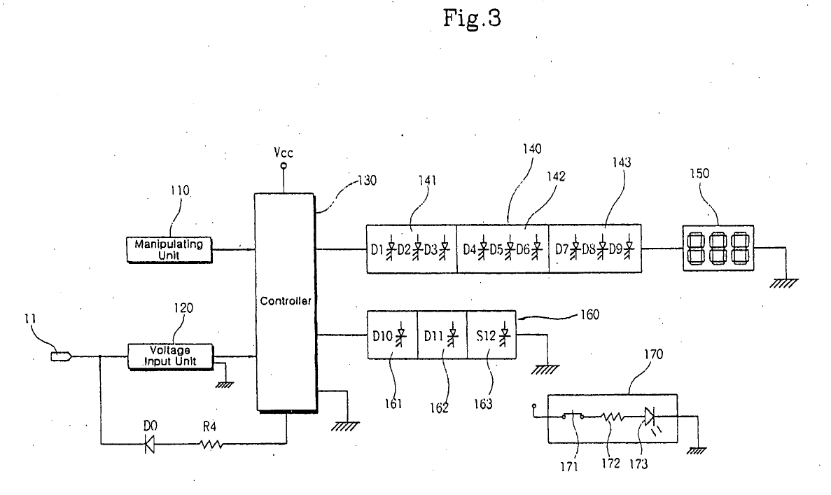

Referring now to FIG. 3, the body (10) includes a manipulating unit (110), a power input unit (120), a controller (130), a measurement indicating lamp unit (140), a segment indicating unit (150), a mode indicating lamp unit (160), an illuminating lamp unit (170), and a battery (not shown).

The manipulating unit (10) includes a plurality of manipulating buttons (111, 112) mounted at an indication/manipulation panel (12), and when the manipulating buttons (111, 112) are manipulated, a key signal corresponding thereto is generated to be inputted to the controller (130).

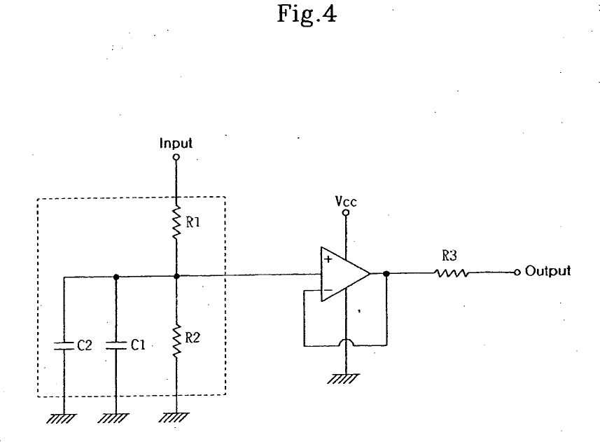

The power input unit (120) serves to input a voltage measured by the probe (11) to the controller (130) and to input a voltage outputted from the controller (130) itself to the controller (130). For example, as shown in FIG. 4, the power input unit (120) may be the known voltage floor circuit where a non-inversion terminal (+) of an operational amplifier (121) is connected to a voltage input end via voltage dividing/smoothing circuit (122) comprised of a plurality of resistant elements (R1, R2) and capacitors (C1, C2), and an inversion terminal (−) is directly connected to an output terminal. For reference, an unexplained reference numeral R3 is an element-protecting resistance of an output end of the operational amplifier (121).

The controller (130) functions to input a predetermined level of test voltage (for example, approximately 1 volt) to an input end of the voltage input unit (120) via a resistance (R4) and a diode (DO) and to detect a voltage level inputted from the voltage input unit (120) to output a control signal for displaying an indication of ground when the detected voltage level is below zero (0) potential, displaying an indication of a measurement stand-by state when the detected voltage level is at test voltage level and displaying a detected voltage level when the detected voltage level is above the predetermined reference voltage (for example, 3 volts).

The measurement indicating lamp unit (140) includes a plurality of lamps (141-143) disposed at the indication/manipulation panel (12), and each lamp (141-143) is equipped with a plurality of light emitting diodes (LEDs, D1-D9), each diode illuminating a different color. LEDs (D1-D9) at the respective lamps (141-143) are constructed such that one among the LEDs (D1-D9) in correspondence to a relevant detected voltage illuminates according to the control of the controller (130).

The segment indicating unit (150) mounted at the indication/manipulation panel (12) includes a predetermined number of digit segments for indicating numericals or characters by using illuminating elements such as LEDs, and indicates a measured value such as a voltage or the like, a ground stage, a measurement stand-by state or the like, by the control of the controller (130).

The mode indicating lamp unit (160) includes lamps (161, 162) for indicating a measurement mode and a low voltage warning lamp (163) for warning of a low voltage below a predetermined level of voltage. Each lamp (161-163) is illuminated by each LED element (D10-D12) that is driven by the control of the controller (130).

The illuminating lamp unit (170) is comprised of a push button (171) mounted at the indicating/manipulating panel (12) and an LED (173) mounted at a distal end of the body (10) where a short circuit preventing resistance (172) and a probe (11) are disposed.

The LED (173) used for illumination needs to generate a sufficient brightness such that it is preferred that an LED element having a high brightness is used for the LED (173).

For reference, a ground end of each component equipped at the body (10) thus described is connected to a ground end of a measured object via ground connecting means (20).

The operational merits of the present invention thus constructed will now be described with reference to the attached drawings.

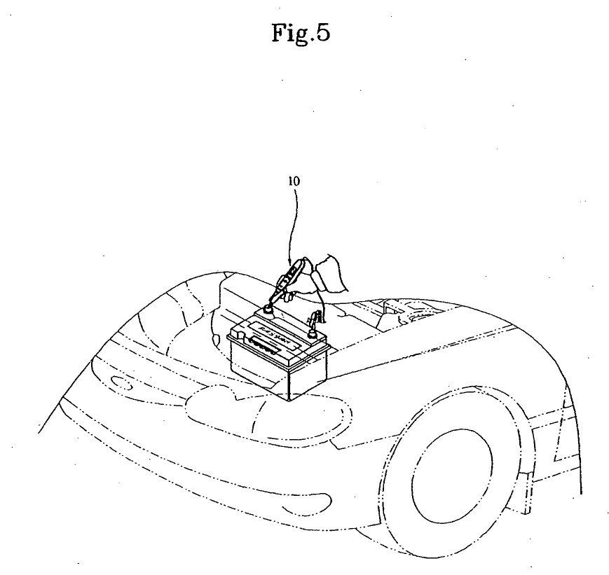

Referring to FIG. 5, when a ground end (such as a negative (−) electrode of a vehicle battery or a vehicle body itself) of a measured object is clamped by the terminal-contacting tong (23) and the manipulating button (112) is manipulated and the body (10) is turned on while a user couples a plug (21) of the ground contacting means (20) to the body (10), a test voltage (for example, approximately 1 volt) outputted from the controller (130) is inputted to the voltage input unit (120) as the probe (11) is not in touch with a measured object.

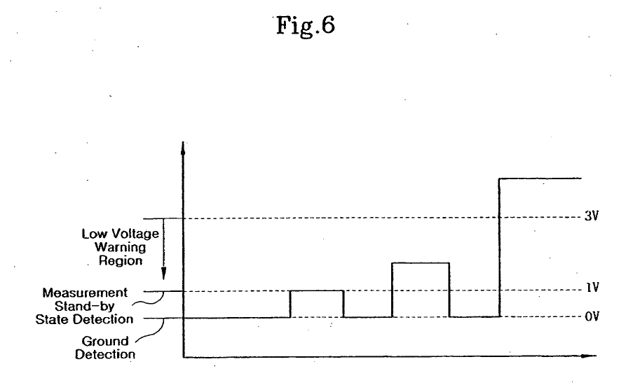

Successively, as shown in FIG. 6, the controller (130) discriminates an input of a test voltage level (for example, approximately 1 volt) from the voltage input unit (120) to indicate a message showing a measurement stand-by state via the segment indicating unit (150).

Under the measurement stand-by state, when a user contacts the probe (11) to a positive (+) electrode of a measured object, voltage of the positive (+) electrode at the measured object is inputted to the controller (13) via the voltage input unit (120).

The controller (130) compares the voltage inputted from the voltage input unit (120) with a predetermined level of voltage (for example, approximately 3 volts), and as a result of the comparison, if the inputted voltage is below the predetermined level, the low voltage warning lamp (163) of the mode indicating lamp unit (160) is illuminated to thereby warn the user against the low voltage state, as shown in FIG. 6.

If the input voltage is above the predetermined level of voltage, the controller (130) numerically displays the voltage detected via the segment indicating unit (150), and a predetermined LED in correspondence to a relevant detected voltage is lighted among the LEDs (D1-D9) of the measurement indicating lamp unit (140), whereby the user can easily and intuitively recognize the present state of the detected voltage.

The controller (130) displays a message (for example, “0.0” or the like) indicating a ground potential via the segment indicating unit (150) because a voltage of a below-zero potential is inputted to the voltage input unit (120) when the user contacts the probe (11) to the negative (−) electrode or a ground terminal of the measured object. At the same time, a predetermined LED which is set to indicate a zero potential is lighted among the LEDs (D1-D9) of the measurement indicating lamp unit (140).

Meanwhile, when it is difficult to see a measured object due to darkness, the LED (173) that is embedded in the illuminating lamp unit (170) is lighted when the push button (171) is pressed to allow the probe (11) to illuminate a pointed place, thereby enabling to easily check a terminal of a measured object.

The portable electric testing equipment thus described according to the present invention is useful for testing various sensors and electric and electronic appliances of a vehicle in a repair shop, particularly for testing a performance of a battery, a power window motor, an injector, a power transistor, a throttle position sensor, an oxygen sensor, a vehicle speed sensor, an air flow sensor, an engine starting control relay, a pulse generator for automatic transmission, a wheel speed sensor, a Manifold Absolute Pressure Sensor (MAP Sensor), rotating sensor of an injection pump, a failure checking of an antenna, a horn, a wiper and the like.

The foregoing description of the preferred embodiment of the present invention has been presented for the purpose of illustration and description. It is not intended to be exhaustive or to limit the invention to the precise form disclosed, and modifications and variations are possible in light of the above teachings or may be acquired from practice of the invention. It is intended that the scope of the invention be defined by the claims appended hereto, and their equivalents.

Although in the preferred embodiment of the present invention, a construction for measuring a voltage is only explained. It has only exemplified essential parts related to the invention such that other constructions may be included for measuring and indicating frequencies, resistances, currents and the like using the known arts.

As apparent from the foregoing, there is an advantage in the portable electric testing equipment thus described according to the embodiment of the present invention in that when a test voltage is inputted to a voltage input unit to apply a voltage level corresponding to the test voltage, it is recognized as a measurement stand-by state and is indicated as such, whereby a user can easily tell the measurement stand-by state.

There is another advantage in that a plurality of lamps can be selectively lighted according to a measured voltage to allow a user to easily and instinctively tell a measured voltage.

What is claimed is:

1. A portable electric testing equipment comprising:
a probe;
ground contact means for contacting a ground terminal of a measured object;
a voltage input unit for receiving a voltage applied from said probe;
a controller for applying a test voltage of a prescribed level to said voltage input unit, and
outputting a control signal for indicating a ground when a voltage level inputted from said voltage input unit is below zero level and for indicating a measurement stand-by state when the voltage level is at test voltage level and for indicating a detected voltage level when the voltage level is above a prescribed reference voltage; and
display means for performing an indication according to the control signal from said controller.

2. The equipment as defined in claim 1, wherein said display means comprises a segment indicating unit.

3. The equipment as defined in claim 1, wherein said display means comprises a plurality of light emitting elements, each being illuminated according to a detected voltage range.

4. The equipment as defined in claim 1, wherein said display means comprises a low voltage warning light emitting element for being illuminated when a voltage below said prescribed reference voltage is detected.

5. The equipment as defined in claim 1 further comprising probe extension means having an attachable/detachable coupling unit, an extension cable, and an auxiliary probe connected to said extension cable.

6. The equipment as defined in claim 1 further comprising an illuminating lamp for illuminating a place at the pointing direction of said probe.
